(19) United States
(12) Patent Application Publication
(10) Pub. No.: US 2018/0298489 A1
(43) Pub. Date: Oct. 18, 2018

(54) DEPOSITION APPARATUS, METHOD FOR CONTROLLING SAME, DEPOSITION METHOD USING DEPOSITION APPARATUS, AND DEVICE MANUFACTURING METHOD

(71) Applicant: JOLED INC., Tokyo (JP)

(72) Inventor: Akira TAKIGUCHI, Tokyo (JP)

(73) Assignee: JOLED INC., Tokyo (JP)

(21) Appl. No.: 16/015,946

(22) Filed: Jun. 22, 2018

Related U.S. Application Data
(63) Continuation of application No. 15/124,170, filed on Sep. 7, 2016.

(30) Foreign Application Priority Data
Mar. 11, 2014 (JP) 2014-048024

(51) Int. Cl. C23C 14/54; C23C 14/24; C23C 14/56; H01L 51/52; C23C 14/12; H01L 51/56

(52) U.S. Cl. CPC C23C 14/542; C23C 14/24; C23C 14/564; C23C 14/243; C23C 14/12; H01L 51/56; H01L 51/5215

(57) ABSTRACT

A vapor deposition method for depositing different vapor deposition materials onto a vapor deposition target provided in a chamber is disclosed. A first vapor deposition material is heated, via a first heater, for a predetermined period for increasing a temperature of the first vapor deposition material. Based on the increased heat, vapor of the first vapor deposition material is ejected from a first vapor deposition source towards the vapor deposition target. After the predetermined period has elapsed and via a second heater, the second vapor deposition material is heated for increasing a temperature of a second vapor deposition material. Based on the increased heat, vapor of the second vapor deposition material is ejected from a second vapor deposition source towards the vapor deposition target. The first vapor deposition material contains an organic functional material, and the second vapor deposition material contains a metal material.

### CROSS REFERENCES TO RELATED APPLICATIONS

This Application is a continuation application of the pending U.S. patent application Ser. No. 15/124,170, filed on Sep. 7, 2016, which is a National Stage Application of PCT/JP2015/000886, filed on Feb. 23, 2015, which claims priority from Japanese Patent Application No. 2014-048024, filed on Mar. 11, 2014, the contents of which are hereby incorporated by reference in their entireties.

### TECHNICAL FIELD

The present invention relates to a vapor deposition apparatus used in device manufacture, a control method of the vapor deposition apparatus, a vapor deposition method using the vapor deposition apparatus, and a device manufacturing method. In particular, the present invention is related to a vapor deposition apparatus, a control method of the vapor deposition apparatus, and a vapor deposition method, where the vapor deposition apparatuses each have eject outlets and the vapor deposition apparatuses eject vapor deposition materials differing from one another from the respective eject outlets to the inside of a chamber.

### BACKGROUND ART

Devices such as organic light-emitting elements and thin film transistors (referred to in the following as TFTs) include organic functional layers having specific functions. Examples of such organic functional layers include organic light-emitting layers in organic light-emitting elements and organic semiconductor layers in TFTs. For example, a typical organic light-emitting element has a substrate, and in addition to the substrate, a metal electrode, multiple organic functional layers, and a light-transmissive electrode layer disposed in the stated order above the substrate. Each of such layers of the organic light-emitting element is usually formed by performing vacuum vapor deposition in a chamber. A typical chamber used for vacuum vapor deposition is a high vacuum chamber having a substrate at an upper portion and a vapor deposition source at a lower portion thereof. One example of such a chamber is disclosed in Patent Literature 1. For example, the vapor deposition source has a crucible inside that accommodates an organic substance. Further, a heating device is disposed around the crucible. The organic substance accommodated in the vapor deposition source is heated to evaporate, whereby the organic substance in the form of gas spreads inside the chamber. Further, the organic substance transforms into a solid from the gas form when coming in contact with the substrate. Thus, an organic functional layer in the form of a thin film is formed on the substrate.

In the field of organic light-emitting elements, a proposal has been made of a vapor deposition apparatus having two vapor deposition sources disposed inside the chamber, the first vapor deposition source for a vapor deposition material that is the main material for forming an organic thin film, and the second vapor deposition source for an extremely small amount of a specific additive vapor deposition material. One example of such a vapor deposition apparatus is disclosed in Patent Literature 2. Patent Literature 2 discloses that the vapor deposition apparatus performs co-deposition of forming a functional layer of an organic light-emitting element by depositing both materials on the substrate at the same time, and that an organic light-emitting element whose functional layer is formed in such a manner has improved light-emission characteristics, such as improved light-emission efficiency and improved luminance.

### CITATION LIST

### Patent Literature

### [Patent Literature 1]

Japanese Patent Application Publication No.: 2005-310471

### [Patent Literature 2]

Japanese Patent Application Publication No.: H10-195639

### SUMMARY OF INVENTION

### Technical Problem

Here, one problem occurring when vapor-depositing vapor deposition material on a substrate to form a functional layer is the introduction of an undesirable substance into the vapor deposition material. In the present disclosure, the term “undesirable substance” may refer to, for example, a very small amount of moisture, etc., in the atmosphere that enters the chamber when placing the vapor deposition material inside the chamber. Also, the term “undesirable substance” may refer to, for example, when co-deposition is being performed, a compound such as an oxide or a hydroxide of the other vapor deposition material having scattered into the chamber. In particular, when performing co-deposition by using, as one vapor deposition material, a material that readily reacts with an undesirable substance, the vapor deposition material may undergo degradation through reaction with the undesirable substance, which is problematic.

The present invention aims to provide a vapor deposition apparatus, a control method of the vapor deposition apparatus, a vapor deposition method in which the vapor deposition apparatus is used, and a device manufacturing method that reduce degradation of material characteristics of vapor deposition material in co-deposition.

### Solution to Problem

In order to achieve this aim, one aspect of the present invention is a vapor deposition apparatus that performs co-deposition to deposit different vapor deposition materials onto a vapor deposition target, the vapor deposition apparatus including: a chamber accommodating the vapor deposition target; a first vapor deposition source ejecting vapor of a first vapor deposition material towards the vapor deposition target; a second vapor deposition source ejecting vapor of a second vapor deposition material differing from the first vapor deposition material towards the vapor deposition target; a first heater heating the first vapor deposition material; a second heater heating the second vapor deposition material; and a heat controller controlling the first and second heaters. The vapor deposition apparatus pertaining to one aspect of the present invention is characterized in that the heat controller is capable of controlling the first and second heaters so that increasing of the temperature of the second vapor deposition material is commenced after a predetermined time period has elapsed from commencement of increasing of the temperature of the first vapor deposition material.

### Advantageous Effects of Invention

The vapor deposition apparatus pertaining to one aspect of the present invention prevents undesirable substances ejected from one vapor deposition source from entering another vapor deposition source that accommodates a vapor deposition material that readily reacts with undesirable substances. Thus, the vapor deposition apparatus pertaining to one aspect of the present invention prevents the reaction between undesirable substances and the vapor deposition material that readily reacts with undesirable substances. Thus, degradation of material characteristics of the vapor deposition material is reduced in co-deposition.

### BRIEF DESCRIPTION OF DRAWINGS

FIG. 1 is a schematic cross-sectional view illustrating the structure of a vapor deposition apparatus 1 pertaining to embodiment 1.

FIG. 2 is a schematic illustrating how vapor deposition substances are vapor-deposited onto a substrate inside the vapor deposition apparatus 1.

FIG. 3 is a perspective view illustrating the structure of vapor deposition sources pertaining to embodiment 1.

FIG. 4 is a schematic cross-sectional view illustrating the vapor deposition sources pertaining to embodiment 1.

FIG. 5 schematically illustrates one example of temperature profiles of the vapor deposition sources and a pressure profile inside a chamber 2 in a vapor deposition method in which the vapor deposition apparatus 1 pertaining to embodiment 1 is used.

FIG. 6 schematically illustrates one example of temperature profiles of the vapor deposition sources and a pressure profile inside the chamber 2 in a vapor deposition method in which a vapor deposition apparatus 1 pertaining to modification 1 of embodiment 1 is used.

FIG. 7 schematically illustrates one example of temperature profiles of the vapor deposition sources and a pressure profile inside the chamber 2 in a vapor deposition method in which a vapor deposition apparatus 1 pertaining to modification 2 of embodiment 1 is used.

FIG. 8 schematically illustrates one example of temperature profiles of the vapor deposition sources and a pressure profile inside the chamber 2 in a vapor deposition method in which a vapor deposition apparatus 1 pertaining to modification 3 of embodiment 1 is used.

FIG. 9 schematically illustrates one example of temperature profiles of the vapor deposition sources and a pressure profile inside the chamber 2 in a vapor deposition method in which a vapor deposition apparatus 1 pertaining to modification 4 of embodiment 1 is used.

FIGS. 10A through 10D illustrate processes of a device manufacturing method pertaining to embodiment 2, which is a manufacturing method of an organic EL device.

FIG. 11 is a schematic illustrating a cross-sectional structure of vapor deposition sources in a vapor deposition apparatus that the present inventor used for experimentation/consideration.

FIG. 12 schematically illustrates one example of a temperature profile of vapor deposition sources and one example of a pressure profile inside the chamber 2 in a vapor deposition method that the present inventor experimented with and considered.

FIG. 13 schematically illustrates one example of a temperature profile of the vapor deposition sources in the vapor deposition method that the present inventor experimented with and considered.

FIG. 14 schematically illustrates one example of a temperature profile of the vapor deposition sources in the vapor deposition method that the present inventor experimented with and considered.

### DESCRIPTION OF EMBODIMENTS

<<How Inventor Arrived at Embodiments of Invention>>

In the field of organic light-emitting elements, a technology referred to as co-deposition has been proposed. For co-deposition, two vapor deposition sources are disposed inside a chamber, the first vapor deposition source for a vapor deposition material (referred to in the following as the “main material”) that is the main material for forming an organic thin film, and the second vapor deposition source for an extremely small amount of a specific additive vapor deposition material (referred to in the following as the “additive material”). Further, in co-deposition, the main material and the additive material are vapor-deposited onto a substrate at the same time.

Meanwhile, when performing vacuum vapor deposition, undesirable substances may enter a vapor deposition source along with the vapor deposition material when supplying the vapor deposition material to the vapor deposition source inside the chamber. These undesirable substances may be released from the vapor deposition source when heating is performed, and may react with vapor deposition material to bring about degradation of material characteristics, which is problematic. In particular, in co-deposition using two different vapor deposition materials, one of which more readily reacts with undesirable substances compared to the other, the vapor deposition material readily reacting with undesirable substances may react with the undesirable substances and undergo degradation in material characteristics, which is problematic.

The following explains a technical problem that the present inventor has found with co-deposition through consideration.

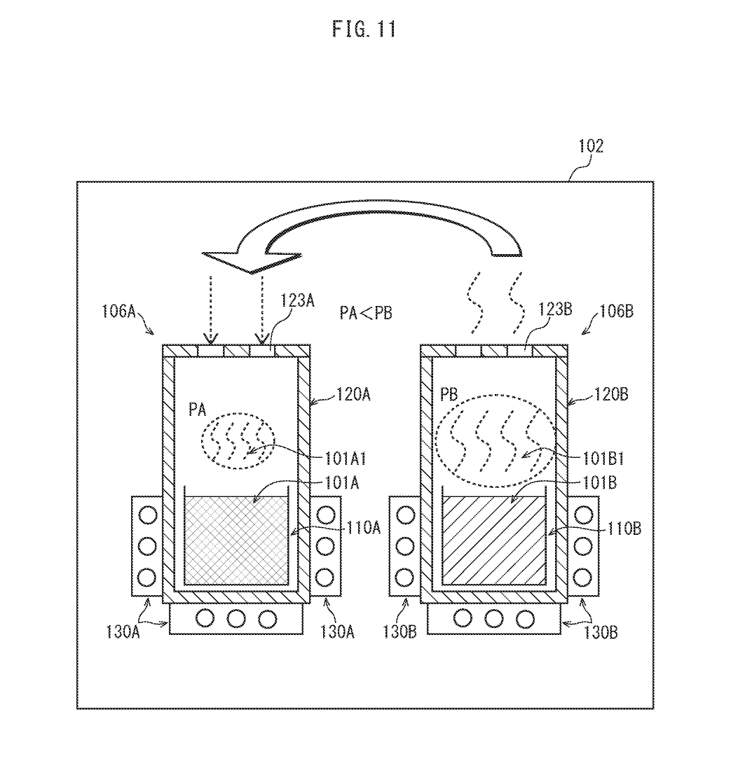

FIG. 11 is a schematic illustrating a cross-sectional structure of vapor deposition sources in a vapor deposition apparatus that the present inventor used for experimentation/consideration. Vapor deposition sources 106A and 106B are disposed inside a chamber 102. (Note that in the following, the alphabets A and B appended to distinguish vapor deposition sources from one another are replaced with the alphabet X when there is no need to distinguish the vapor deposition sources from one another. Further, this similarly applies to the rest of the elements inside the vapor deposition sources and provided for both vapor deposition sources in FIG. 11.) For example, the vapor deposition source 106A has a housing 120A, and inside the housing 120A, a crucible 110A that accommodates a vapor deposition material 101A is disposed. Further, a heating device 130A is disposed around the crucible 110A. The heating device 130A heats the vapor deposition material 101A, which results in vapor 101A1 of the vapor deposition material 101A being ejected from eject outlets 123A to spread inside of the chamber 102. Similarly, the vapor deposition source 106B has a housing 120B, and inside the housing 120B, a crucible 110B that accommodates a vapor deposition material 101B is disposed. Vapor 101B1 of the vapor deposition material 101B, which is generated through heating by a heating device 130B, is ejected from eject outlets 123B to spread inside of the chamber 102. The vapors 101A1 and 101B1 spreading in the chamber 102 mix with one another, and contact the substrate and transform into solids. Thus, an organic functional layer that is in the form of a thin film and that contains the vapor deposition materials 101A and 101B is formed on the substrate.

In such a vapor deposition apparatus, the vapor deposition sources inside the chamber 102 are supplied with the vapor deposition materials through the following processes.

(i) After completion of film deposition, the vapor deposition sources 106X in the chamber 102 are cooled to room temperature, and then the pressure inside the chamber 102 is increased to atmospheric pressure.

(ii) The crucibles 110X of the vapor deposition sources 106X, which hold the vapor deposition materials 10X, are taken out from the chamber 102.

(iii) The crucibles 110X are filled with the respective vapor deposition materials 101X. Each vapor deposition material X is a liquid or a solid at room temperature.

(iv) The crucibles 110X, now full of the vapor deposition materials 101X, are placed inside the respective vapor deposition sources 106X inside the chamber 102 once again.

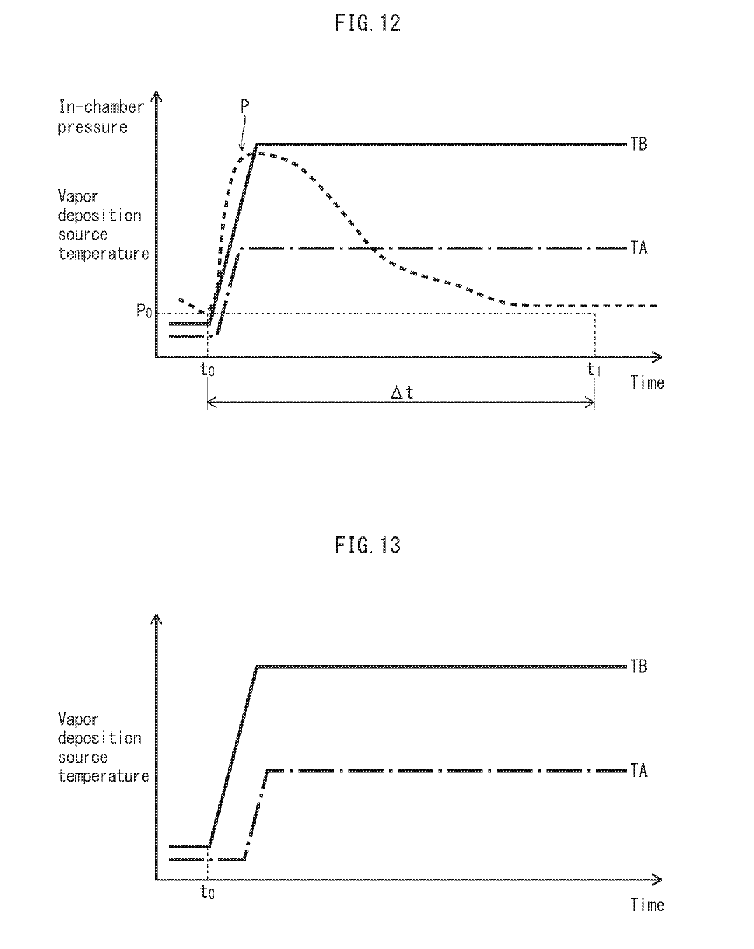

(v) A vacuum environment is created inside the chamber 102, and then the vapor deposition materials 101X are heated. FIG. 12 schematically illustrates one example of a temperature profile of the vapor deposition sources and one example of a pressure profile inside the chamber 2 in a vapor deposition method that the present inventor experimented with and considered. According to FIG. 12, the heating using the heating devices 130A and 130B is started at time point t₀, and the vapor deposition materials 101A and 101B are respectively heated to vapor deposition temperatures TA and TB.

(vi) Film forming through vapor deposition is executed. At this point, the vapor deposition sources 106A and 106B respectively have internal pressures PA and PB, which are respectively in accordance with the vapor deposition rates of the vapor deposition materials 101A and 101B. Here, it should be noted that under the conditions illustrated in FIG. 12, the pressures PA and PB may fulfill PB >PA.

Among the processes described above, undesirable substances may be introduced inside the crucibles 110X along with the vapor deposition materials 101X when supplying the crucibles 110X with the vapor deposition materials 101X in process (iii), and/or may be introduced along with the vapor deposition materials 101X when placing the crucibles 110X in the chamber 102 once again in process (iv). Here, the undesirable substances may for example be originally contained in the vapor deposition materials 101X or may attach to the inner circumferential surfaces of the crucibles when the crucibles are exposed to the atmosphere. Further, the heating in process (v) may cause undesirable substances to evaporate from the vapor deposition materials 101X and/or the crucibles 110X, which results in the undesirable substances spreading inside the chamber 102. The undesirable substances having spread into the chamber 102 remain inside the chamber 102 for a time period At inside the chamber 102, and the pressure P inside the chamber 102 consequently increases. Here, as illustrated in FIG. 12, the time period At is the time period between time points t₀ and t₁. Time point t₀ is when the heating is commenced, and time point t₁ is when undesirable substances, etc., are discharged to the outside of the chamber 102 by using a vacuum pump.

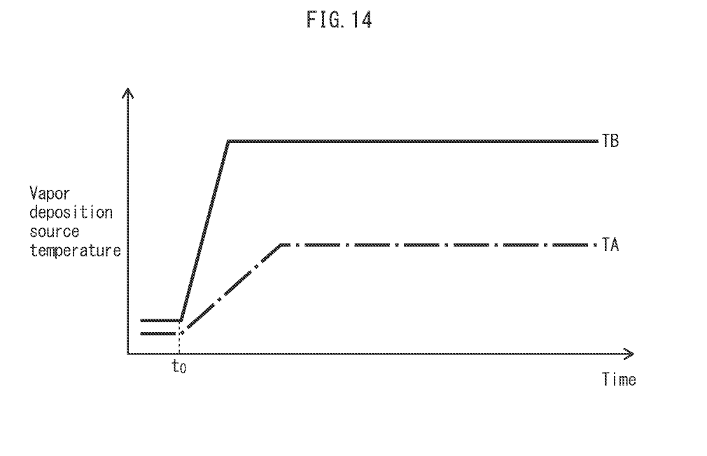

In connection with this, the present inventor has found that when the pressures PA and PB (respectively indicating the pressures inside the vapor deposition sources 106A and 106B) fulfill PB >PA, a reverse flow of gases inside the chamber 102 into the vapor deposition source PA via the eject outlets 123A occurs. For example, the pressures PA and PB may fulfill PB >PA under the following conditions: (i) when the heating with the heating device 130B is commenced earlier than the heating with the heating device 130A, as illustrated in FIG. 13; (ii) the heating speed of the heating device 130B is faster than the heating speed of the heating device 130A, as illustrated in FIG. 14; and (iii) the temperature profiles of the heating devices 130A and 130B are set so that the vapor deposition rate of the vapor deposition material 101B is higher than the vapor deposition rate of the vapor deposition material 101A.

As described above, gases inside the chamber 102 during time period At contain undesirable substances having been ejected from the vapor deposition source 106B to spread inside the chamber 102. If so, the undesirable substances having spread inside the chamber 102 enter the vapor deposition source 106A from the chamber 102 with the gases inside the chamber 102.

In this case, if the vapor deposition material 101A more readily reacts with undesirable substances compared to the vapor deposition material 101B, the vapor deposition material 101A may react with the undesirable substances that are ejected from the vapor deposition source 106B and enter the inside of the vapor deposition source 106A and undergo degradation of material characteristics, which is problematic. Further, with the vapor deposition sources 106X having the housings 120X provided with the eject outlets 123X, the vapor deposition materials 101X, when heated, are in a relatively active state, and thus is in a state where the vapor deposition materials 101X readily react with undesirable substances. In particular, when organic materials are used as the vapor deposition materials 101X, degradation of the vapor deposition materials 101X, such as replacement of hydrogen atoms in the molecules of the organic material with OH groups, is likely to occur. Further, in co-deposition, the mixing of vapors of vapor deposition materials ejected from different vapor deposition sources is not a problem, as long as the mixing occurs on the vapor deposition target. However, for example, when the vapor deposition material 101A mixes with a compound (an oxide and/or a hydroxide) of the vapor deposition material 101B during the increasing of the temperature of the vapor deposition material 101A, the vapor deposition material 101A may undergo degradation.

In view of the problem described above, the present inventor considers that the degradation of a vapor deposition material that readily reacts with undesirable substances, among a plurality of vapor deposition materials 101X, can be effectively prevented by preventing undesirable substances from entering the vapor deposition source that holds the vapor deposition material that readily reacts with undesirable substances. Based on this, the present inventor conducted much research for a method achieving such effect. Through such research, the present inventor has arrived at a vapor deposition apparatus, a control method of the vapor deposition apparatus, a vapor deposition method in which the vapor deposition apparatus is used, and a device manufacturing method that are described in the following embodiments and that reduce degradation of material characteristics of vapor deposition material.

<<Overview of Aspects for Implementing Invention>>

One aspect of the present invention is a vapor deposition apparatus that performs co-deposition to deposit different vapor deposition materials onto a vapor deposition target, the vapor deposition apparatus including: a chamber accommodating the vapor deposition target; a first vapor deposition source ejecting vapor of a first vapor deposition material towards the vapor deposition target; a second vapor deposition source ejecting vapor of a second vapor deposition material differing from the first vapor deposition material towards the vapor deposition target; a first heater heating the first vapor deposition material; a second heater heating the second vapor deposition material; and a heat controller controlling the first and second heaters. The vapor deposition apparatus pertaining to one aspect of the present invention is characterized in that the heat controller is capable of controlling the first and second heaters so that increasing of the temperature of the second vapor deposition material is commenced after a predetermined time period has elapsed from commencement of increasing of the temperature of the first vapor deposition material.

In another aspect of the present invention, the first vapor deposition source may include a first housing that accommodates the first vapor deposition material and that has an eject outlet from which the vapor of the first vapor deposition material is ejected, and the second vapor deposition source may include a second housing that accommodates the second vapor deposition material and that has an eject outlet from which the vapor of the second vapor deposition material is ejected.

In another aspect of the present invention, the heat controller may be capable of controlling the first and second heaters so that a vapor deposition temperature of the second vapor deposition material is higher than a vapor deposition temperature of the first vapor deposition material.

One aspect of the present invention is a control method of using the vapor deposition apparatus pertaining to one aspect of the present invention to perform co-deposition to deposit the first and second vapor deposition materials onto the vapor deposition target. The control method pertaining to one aspect of the present invention is characterized in that when the first vapor deposition method more readily forms a bond with moisture and/or oxygen compared to the second vapor deposition material, the first and second heaters are controlled so that the increasing of the temperature of the second vapor deposition material is commenced after the predetermined time period has elapsed from the commencement of the increasing of the temperature of the first vapor deposition material.

In another aspect, the first and second heaters may be controlled so that a vapor deposition temperature of the first vapor deposition material and a vapor deposition temperature of the second vapor deposition material are such that a vapor deposition rate of the first vapor deposition material is higher than a vapor deposition rate of the second vapor deposition material.

In another aspect, the first heater may be controlled to increase the temperature of the first vapor deposition material from a temperature around room temperature to the vapor deposition temperature of the first vapor deposition material in increments, and the second heater may be controlled to increase the temperature of the second vapor deposition material from a temperature around room temperature to the vapor deposition temperature of the second vapor deposition material in increments.

In another aspect, the first heater may be controlled to first increase the temperature of the first vapor deposition material from a temperature around room temperature to a temperature higher than the vapor deposition temperature of the first vapor deposition material, and then to decrease the temperature of the first vapor deposition material to the vapor deposition temperature of the first vapor deposition material. Further, in another aspect, the second heater may be controlled to first increase the temperature of the second vapor deposition material from a temperature around room temperature to a temperature higher than the vapor deposition temperature of the second vapor deposition material, and then to decrease the temperature of the second vapor deposition material to the vapor deposition temperature of the second vapor deposition material.

One aspect of the present invention is a vapor deposition method in which the control method pertaining to one aspect of the present invention is used to perform co-deposition to deposit the first and second vapor deposition materials onto the vapor deposition target. The vapor deposition method pertaining to one aspect of the present invention is characterized in that the first vapor deposition material is a main material containing an organic functional material, and the second vapor deposition material is an additive material containing a metal material.

One aspect of the present invention is a device manufacturing method in which the vapor deposition method pertaining to one aspect of the present invention is used to form a layer containing the first and second vapor deposition materials on the vapor deposition target.

In the vapor deposition apparatus pertaining to one aspect of the present invention, the heat controller may be further capable of controlling the first and second heaters so that decreasing of the temperature of the first vapor deposition material from a vapor deposition temperature of the first vapor deposition material to a temperature around room temperature is commenced after commencement of decreasing of the temperature of the second vapor deposition material from a vapor deposition temperature of the second vapor deposition material to a temperature around room temperature.

One aspect of the present invention is a control method of using the vapor deposition apparatus pertaining to one aspect of the present invention to perform co-deposition to deposit the first and second vapor deposition materials onto the vapor deposition target. In the control method pertaining to one aspect of the present invention, when the first vapor deposition method more readily forms a bond with moisture and/or oxygen compared to the second vapor deposition material, the first and second heaters may be controlled so that the decreasing of the temperature of the first vapor deposition material from the vapor deposition temperature of the first vapor deposition material to a temperature around room temperature is commenced after commencement of the decreasing of the temperature of the second vapor deposition material from the vapor deposition temperature of the second vapor deposition material to a temperature around room temperature.

In another aspect, the decreasing of the temperature of the first vapor deposition material from the vapor deposition temperature of the first vapor deposition material to a temperature around room temperature may be performed in increments, and the decreasing of the temperature of the second vapor deposition material from the vapor deposition temperature of the second vapor deposition material to a temperature around room temperature may be performed in increments.

One aspect of the present invention is a vapor deposition method in which the control method pertaining to one aspect of the present invention is used to perform co-deposition to deposit the first and second vapor deposition materials onto the vapor deposition target. The vapor deposition method pertaining to one aspect of the present invention is characterized in that the first vapor deposition material is a main material containing an organic functional material, and the second vapor deposition material is an additive material containing a metal material.

One aspect of the present invention is a device manufacturing method in which the vapor deposition method pertaining to one aspect of the present invention is used to form a layer containing the first and second vapor deposition materials on the vapor deposition target.

### Embodiment 1

The following describes a vapor deposition apparatus pertaining to the present embodiment and a device manufacturing method pertaining to the present embodiment in which the vapor deposition apparatus is used, with reference to the accompanying drawings.

<Vapor Deposition Apparatus 1>

(Overall Structure)

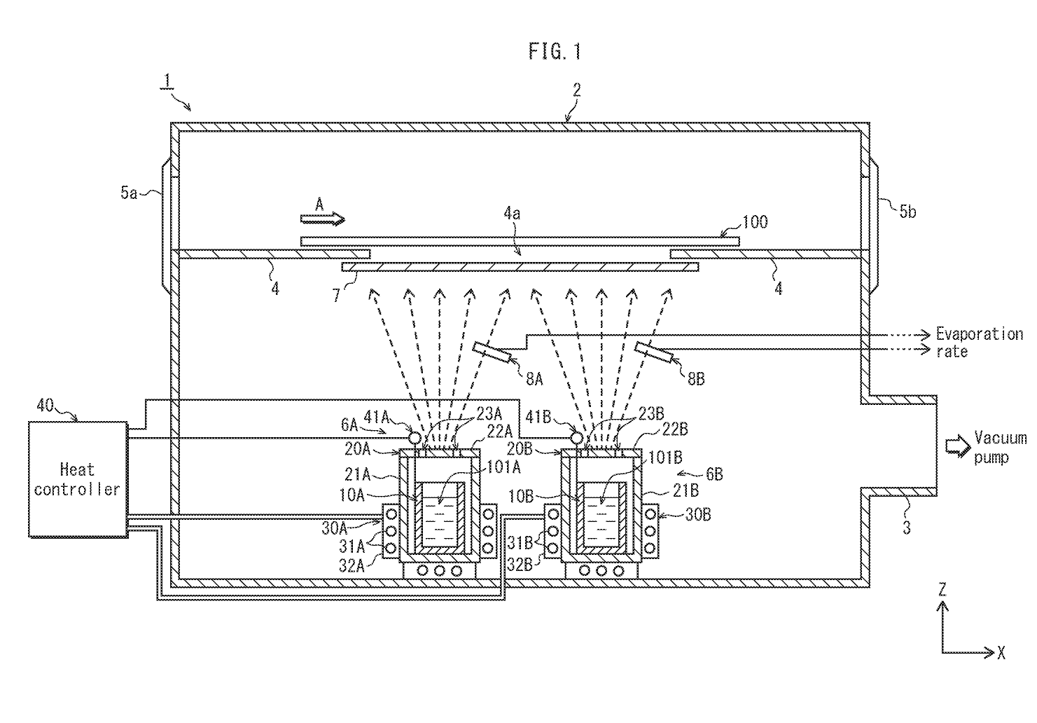

FIG. 1 is a schematic cross-sectional view illustrating the structure of a vapor deposition apparatus 1 pertaining to embodiment 1. The vapor deposition apparatus 1 performs vapor deposition of vapor deposition substances onto a surface of a substrate 100. As illustrated in FIG. 1, the vapor deposition apparatus 1 includes a chamber 2. The chamber 2 has a chamber air outlet 3 that is connected to an undepicted vacuum pump. Thus, a vacuum environment can be created and maintained inside the chamber 2. The space inside the chamber 2 is partitioned into a top part and a bottom part by a partition plate 4, and the substrate 100 is moved above the partition plate 4. The chamber 2 has a lateral wall provided with an entrance 5a and an exit 5b. The substrate 100 is transported into the chamber 2 via the entrance 5a and transported out of the chamber 2 via the exit 5b. Specifically, a transport means transports the substrate 100 into the chamber 5 via the entrance 5a, transports the substrate 100 over the partition plate 4, and transports the substrate 100 out of the chamber 2 via the exit 5b. Note that the transport means transports a plurality of substrates 100 one by one.

Below the partition plate 4 in the chamber 2, a vapor deposition source 6A (first vapor deposition source) and a vapor deposition source 6B (second vapor deposition source) are disposed. The vapor deposition sources 6A and 6B eject the vapor deposition substances. The vapor deposition substances ejected from the vapor deposition source 6A and 6B are, for example, substances for forming an electrode or a functional layer of an organic EL element, and each may be an inorganic substance or an organic substance. For example, the vapor deposition source 6A may accommodate, as a main material for a functional layer of an organic light-emitting element, diamine, TPD, coumarin, or quinacridone, and the vapor deposition source 6B may accommodate, as an additive material, a metal material such as Ba, Ni, Li, Mg, Au, or Ag.

The partition plate 4 has a window 4a formed therein. The window 4a allows the vapor deposition substances ejected from the vapor deposition sources 6A and 6B to pass through. Further, the window 4a is exposed or blocked by a shutter 7. In the vapor deposition apparatus 1 having such a structure, by transporting the substrate 100 while the shutter 7 is open and the vapor deposition substances are being ejected from the vapor deposition source 6A and 6B, the vapor deposition substances pass through the window 4a and are vapor-deposited onto a bottom surface of the substrate 100.

Inside the chamber 2 and above the vapor deposition source 6A, a sensor 8A is disposed that measures the amount of vapor deposition substance supplied from the vapor deposition source 6A to the substrate 100 per unit time. In other words, the sensor 8A measures the evaporation rate of the vapor deposition source 6A. Further, inside the chamber 2 and above the vapor deposition source 6B, a sensor 8B is disposed that measures the evaporation rate of the vapor deposition source 6B. The evaporation rates measured by the sensors 8A and 8B are used to set the transportation speed of the substrate 100, and the like. When depositing the vapor deposition substances to form a predetermined pattern on the substrate 100, vapor deposition is performed with a mask having the predetermined pattern formed therein attached to the bottom surface of the substrate 100.

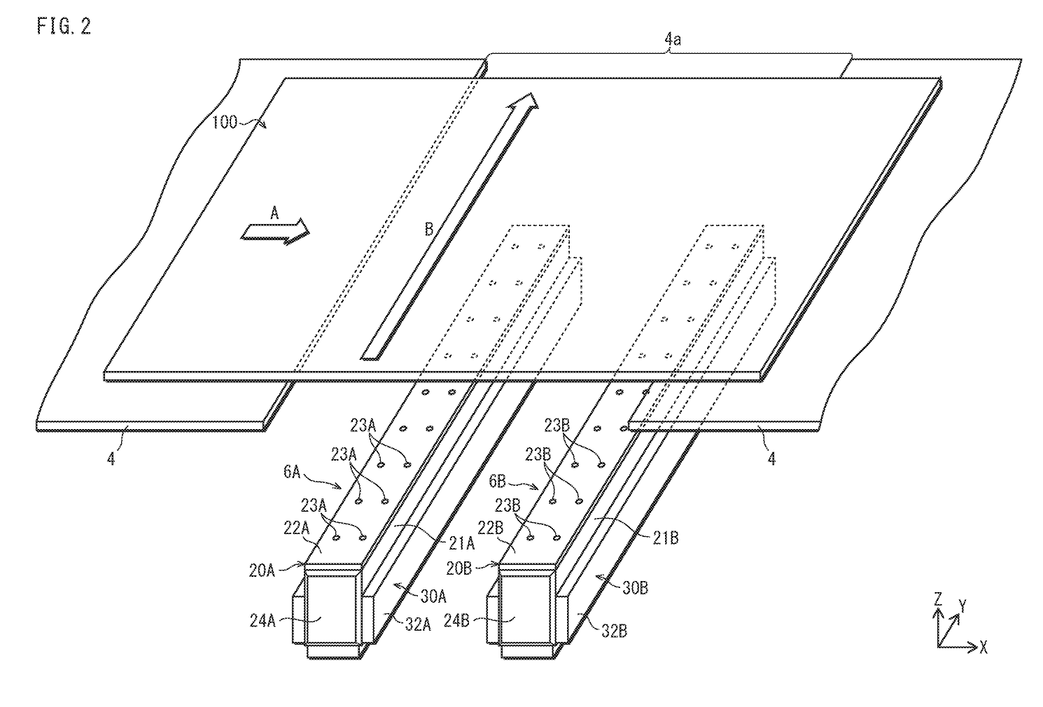

FIG. 2 is a schematic illustrating how the vapor deposition substances are vapor-deposited onto the substrate 100 inside the vapor deposition apparatus 1. FIG. 2 illustrates the vapor deposition apparatus 1 with the window 4a exposed. Further, as illustrated in FIG. 2, each of the vapor deposition sources 6A and 6B is a so-called line source, having a linear shape and extending in a width direction B. The width direction B is a direction perpendicular to the direction in which the substrate 100 is transported (referred to in the following as a transport direction A). The vapor deposition sources 6A and 6B are arranged so that the longitudinal directions thereof are parallel. While the substrate 100 is being transported in the transport direction A, the vapor deposition substances from the vapor deposition sources 6A and 6B pass through the window 4a and are vapor-deposited onto the bottom surface of the substrate 100.

The vapor deposition apparatus 1 performs co-deposition to form a functional layer by depositing both the main material and the additive material at the same time on the deposition target 100. Specifically, referring to the vapor deposition substance evaporation rates measured by the sensors 8A and 8B, control is performed so that the ratio of the evaporation rate of the additive material to the evaporation rate of the main material equals a predetermined ratio. Thus, the vapor deposition apparatus 1 is capable of producing functional layers with improved light-emission characteristics, such as improved light emission efficiency and improved luminance.

(Vapor Deposition Sources 6)

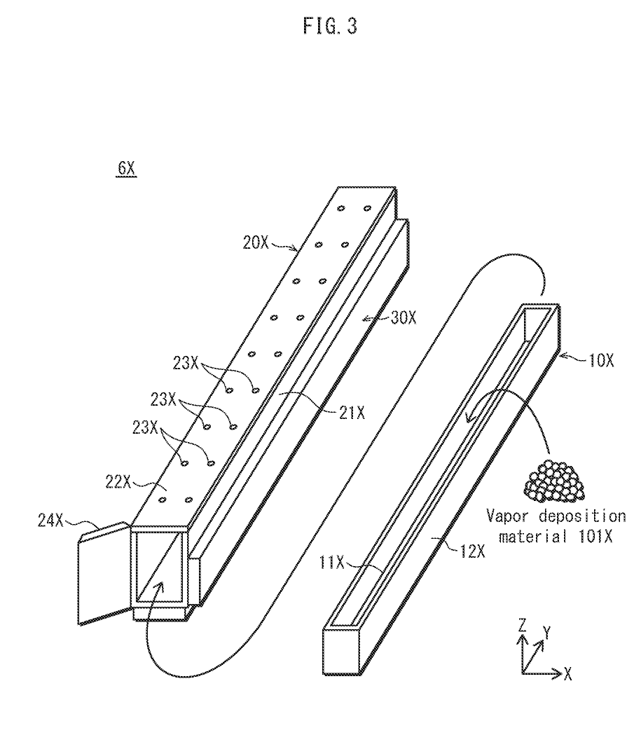

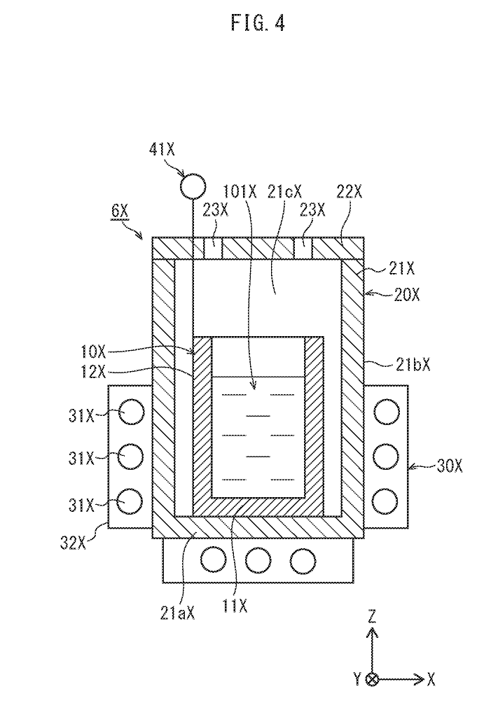

FIG. 3 is a perspective view illustrating the structures of the vapor deposition sources 6A and 6B. (Note that in the following, the alphabets A and B appended to distinguish vapor deposition sources from one another are replaced with the alphabet X when there is no need to distinguish the vapor deposition sources from one another. Further, this similarly applies to the rest of the components inside the vapor deposition sources and provided for both vapor deposition sources in FIGS. 1 and 2.) FIG. 4 is a schematic cross-sectional view illustrating the vapor deposition sources 6X. Each vapor deposition source 6X includes a crucible 10X, a housing 20X, and a heater 30X. The housing 20X and the heater 30X are installed in the bottom part space of the chamber 2. The crucible 10X accommodates a vapor deposition material 101X that becomes a vapor deposition substance. The housing 20X accommodates the crucible 10X therein. The heater 30X covers the circumference of the housing 20X and the bottom of the housing 20X. The crucible 10X is a container that has an elongated shape and that contains the vapor deposition material 101X. The crucible 10X has a bottom plate 11X and a lateral plate 12X, and the top of the crucible 10X is open. For example, the crucible 10X can be manufactured by molding a plate of stainless steel into a cuboid shape. Examples of materials other than stainless steel that can be used for manufacturing the crucible 10X include plates of carbon, titanium, tantalum, and molybdenum. Meanwhile, the housing 20X has the shape of an elongated cuboid having an internal space in which the crucible 10X can be accommodated.

The housing 20X is composed of a main body 21X, a lid 22X, and a door 24X. The main body 21X has an elongated cuboid shape and defines a concave space 21cX for accommodating the crucible 10X. The lid 22X covers a top opening of the concave space 21cX. The door 24X is openable/closable. The door 24X, when open, exposes an opening at one end of the main body 21X, whereas the door 24X, when closed, blocks the opening at the end. Further, the lid 22X has lines of eject outlets 23 disposed therein. The main body 21X, the lid 22X, and the door 24X are each manufactured by molding a metal plate (e.g., a plate of stainless steel).

The main body 21X has a rectangular bottom plate 21aX and a circumferential wall 21bX. The lid 22X is fixed on top of the circumferential wall 21bX by using a screw and/or the like. The door 24X is attached in openable/closable state to the above-described end of the main body 21X by using a hinge and/or the like.

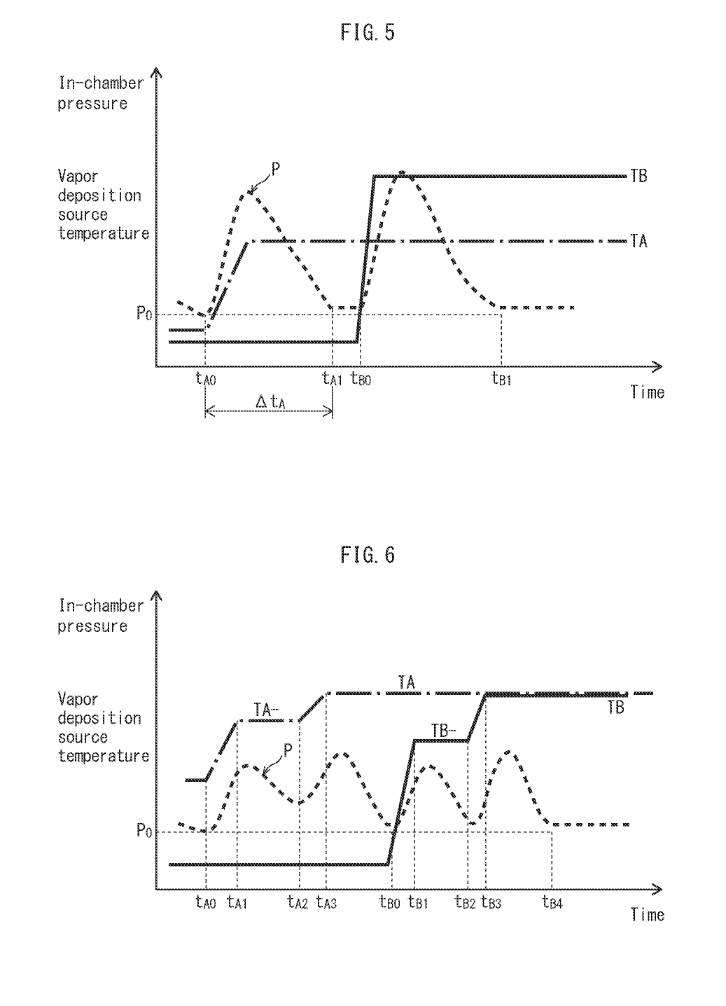

The heater 30X is disposed to cover the bottom plate 21aX of the main body 21X and a lower part of the outside surface of the circumferential wall 21bX of the main body 21X. For example, the heater 30X is composed of a combination of a heater case 32X and a plurality of sheath heaters 31X accommodated inside the heater case 32X. The heater 30X is connected to a heat controller 40. Further, the housing 20X has attached thereto a temperature sensor 41X that measures the temperature of the vapor deposition source 6X. The heat controller 40 monitors the temperature measured by the temperature sensor 41X, and controls output of the heater 30X so that the temperature measured by the temperature sensor 41X equals certain preset temperatures (refer to the temperature profiles illustrated in FIG. 5).

In each vapor deposition source 6X having the above-described structure, vapor generated by heating the vapor deposition material 101X inside the crucible 10X by using the heater 30X (i.e., the vapor deposition substance) fills the housing 20X before being ejected from the eject outlets 23X disposed in the lid 22X in lines. Here, the lid 22X closes the top opening of the main body 21X. The top opening is located above the crucible 10X. Due to this, the vapor deposition substance so generated (i.e., the vapor of the vapor deposition material 101X), after filling the inside of the housing 20X, is ejected from the respective eject outlets 23X at the same pressure due to the internal pressure of the housing 20X. That is, the internal space of the housing 20X functions as a buffer that temporarily stores therein the vapor of the vapor deposition material 101X, and with the internal pressure of the housing 20X slightly higher than the pressure outside the housing 20X, the vapor deposition substance is ejected in regulated state from the respective eject outlets 23X, which are disposed in lines extending along the Y direction. According to this method, even when the temperature of the vapor deposition material differs at different portions thereof along the longitudinal direction before evaporation, vapor of the vapor deposition material is ejected into the chamber 2 at a uniform evaporation rate due to the vapor temporarily filling the inside of the housing 20X before being ejected into the chamber 2. As a result, the film formed through the vapor deposition has a high level of uniformity in terms of thickness along the substrate width direction.

Typically, when performing vacuum vapor deposition with respect to a surface of a vapor deposition target (e.g., a substrate), unevenness in evaporation rate, film thickness, etc., at different areas of the surface occurs. This, for example, leads to organic light-emitting elements with different luminance levels being formed. Meanwhile, with the vapor deposition apparatus 1, even if the temperature of the vapor deposition material differs at different areas along the longitudinal direction, vapor is ejected to the inside of the chamber at the same evaporation rate from different eject outlets by causing the vapor of the vapor deposition material to temporarily fill the inside of the crucible, as described above. Thus, it is expected that the influence on the variance in evaporation rate in the longitudinal direction can be reduced.

<Vapor Deposition Method using Vapor Deposition Apparatus 1>

The following describes the processes involved in performing vapor deposition with respect to a surface of the substrate 100 by using the vapor deposition apparatus 1. In the present embodiment, description is provided of an example where the vapor deposition material 101A (first vapor deposition material) more readily reacts with undesirable substances compared to the vapor deposition material 101B (second vapor deposition material). The vapor deposition material 101A more readily reacting with undesirable substances compared to the vapor deposition material 101B means that the vapor deposition material 101A more readily forms bonds with moisture and/or oxygen compared to the vapor deposition material 101B. FIG. 5 schematically illustrates one example of temperature profiles of the vapor deposition sources and a pressure profile inside the chamber 2 in a vapor deposition method in which the vapor deposition apparatus 1 pertaining to embodiment 1 is used. With the vapor deposition apparatus 1, the temperature and the pressure of the vapor deposition sources 6 are controlled based on the temperature profiles illustrated in FIG. 5A. First, the crucibles 10X are filled with the respective vapor deposition materials 101X, the crucibles 10X are placed in the respective housings 20X inside the chamber 2, and the doors 24X are closed, as illustrated in FIG. 3.

Then, with the shutter 7 shut, a substrate 100 is transported inside the chamber 2 via the entrance 5a and the vacuum pump is actuated to reduce the pressure inside the chamber 2 from atmospheric pressure to high vacuum pressure P₀ (e.g., between 0.1 Pa and 10⁻⁵ Pa).

When the pressure inside the chamber 2 has dropped to high vacuum pressure P₀ at time point t_{A0}, the heater 30A (first heater) of the vapor deposition source 6A is actuated with the high vacuum pressure P₀ maintained inside the chamber 2, to heat the crucible 10A. Then, the temperature of the vapor deposition source 6A is increased at a steep temperature gradient until it reaches a temperature TA to which the vapor deposition source 6A is heated during vapor deposition (referred to in the following as a vapor deposition temperature TA). The vapor deposition temperature TA is higher than the temperature at which the vapor deposition material 101A inside the crucible 10A starts to evaporate, and is within a range of for example 250 degrees Celsius to 350 degrees Celsius.

In the process of being increased to the vapor deposition temperature TA, the temperature of the vapor deposition source 6A exceeds a gas separation temperature of the vapor deposition material 101A. Specifically, the gas separation temperature of the vapor deposition material 101A is a temperature at which undesirable substances having attached to the vapor deposition material 101A separate from the vapor deposition material 101A, and is within a range of for example 100 degrees Celsius to 200 degrees Celsius. When the temperature of the vapor deposition source 6A exceeds the gas separation temperature of the vapor deposition material 101A, undesirable substances having attached to the vapor deposition material 101A are discharged to the outside of the housing 20A via the eject outlets 23A, and consequently increase the pressure inside the chamber 2.

Subsequently, when a sufficient amount of undesirable substances has been removed from vapor deposition material 101A at time point t_{A1}, the pressure inside the chamber 2 decreases to be around the high vacuum pressure P₀ once again. Specifically, length of the time period Δt_{A} between time points t_{A0} and t_{A1} can be determined, for example, by performing analysis of gases to measure the amount of undesirable substances discharged from the vapor deposition material 101A when heated, and determining the amount of time required for sufficient removal of the undesirable substances based on the amount of undesirable substances discharged.

When the pressure inside the chamber 2 has been dropped to around the high vacuum pressure P₀ at time point t_{B0}, which is after the gas separation time period Δt_{A}, the heater 30B (second heater) of the vapor deposition source 6B is actuated with the pressure inside the chamber 2 maintained around the high vacuum pressure P₀, to heat the crucible 10B. Then, the temperature of the vapor deposition source 6B is increased at a steep temperature gradient until it reaches a temperature TB to which the vapor deposition source 6B is heated during vapor deposition (referred to in the following as a vapor deposition temperature TB). The vapor deposition temperature TB is higher than temperature at which the vapor deposition material 101B inside the crucible 10B starts to evaporate, and is within a range of for example 250 degrees to 350 degrees Celsius. In the process of being increased to the vapor deposition temperature TB, the temperature of the vapor deposition source 6B exceeds a gas separation temperature of the vapor deposition material 101B. When the temperature of the vapor deposition source 6B exceeds the gas separation temperature of the vapor deposition material 101B, undesirable substances having attached to the vapor deposition material 101B are discharged to the outside of the housing 20B via the eject outlets 23B, and increase the pressure inside the chamber 2. Subsequently, when a sufficient amount of undesirable substances has been removed from vapor deposition material 101B at time point t_{B1}, the pressure inside the chamber 2 is decreased to be around the high vacuum pressure P0 once again.

Typically, with the vapor deposition sources 6X having the housings 20X provided with the eject outlets 23X, the vapor deposition materials 101X, when heated, are in a relatively active state, and thus is in a state where the vapor deposition materials 101X readily react with undesirable substances. In particular, when organic materials are used as the vapor deposition materials 101X, degradation of the vapor deposition materials 101X, such as replacement of hydrogen atoms in the molecules of the organic material with OH groups, is likely to occur.

Further, in co-deposition, the mixing of pure vapors of vapor deposition materials ejected from different vapor deposition sources is not a problem, as long as the mixing occurs on a substrate that is the vapor deposition target. However, for example, when the vapor deposition material 101A mixes with a compound (an oxide and/or a hydroxide) of the vapor deposition material 101B during increasing of the temperature of the vapor deposition material 101A, the vapor deposition material 101A may undergo degradation. In view of this, the present vapor deposition method is configured so that during a period between time point t_{A0}, where increasing of the temperature of the vapor deposition source 6A is commenced, and time point t_{B0}, where increasing of the temperature of the vapor deposition source 6B is commenced, pressures PA and PB (respectively indicating the pressures inside the vapor deposition sources 6A and 6B) fulfill PA>PB. This means that the heat controller 40 controls the heaters 30A and 30B so that the increasing of the temperature of the vapor deposition material 101B is commenced after a predetermined time period has elapsed from the commencement of the increasing of the temperature of the vapor deposition material 101A. Due to this, during the time period between time point t_{A0} and time point t_{B0}, a reverse flow of gases into the housing 20A of the vapor deposition source 6A via the eject outlets 23A of the vapor deposition source 6A is prevented.

In the present disclosure, when increasing of the temperature of the vapor deposition material 101B is commenced after the predetermined time period has elapsed from commencement of increasing of the temperature of the vapor deposition material 101A, PB>PA is not fulfilled at any point during the heating by the heater 30A.

Consequently, while the vapor deposition source 6A accommodating the vapor deposition material 101A that readily reacts with undesirable substances is being heated, undesirable substances are prevented from entering the vapor deposition source 6A along with gases discharged from the vapor deposition source 6B. Accordingly, degradation of material characteristics of the vapor deposition material 101A is prevented, which would otherwise occur when undesirable substances discharged from the vapor deposition source 6B enter inside the vapor deposition source 6A and react with the vapor deposition material 101A.

Note that the heaters 30A and 30B may be controlled to fulfill PA>PB by setting a higher heating speed to the heater 30A than to the heater 30B. Also, the heaters 30A and 30B may be controlled to fulfill PA>PB by temperature profiles of the heaters 30A and 30B being set so that the vapor deposition rate during the increasing of temperature is higher for vapor deposition material 101A than for vapor deposition material 101B. Controlling the heaters 30A and 30B in such manners also achieves the effects described above.

Once time point t_{B0} is reached, the vapor deposition sources 6A and 6B are maintained at the vapor deposition temperatures TA and TB, respectively. Subsequently, vapor deposition onto the substrate 100 is performed after a sufficient amount of undesirable substances has been removed from the vapor deposition material 101B and the pressure inside the chamber 2 has been decreased to the high vacuum pressure P₀ at time point t_{B1}. Specifically, once the evaporation rate of the vapor deposition material 101A and the evaporation rate of the vapor deposition material 101B, which are respectively measured by the sensor 8A and sensor 8B, become stable, the shutter 7 is opened, and the vapor deposition substances are deposited onto the bottom surface of the substrate 100 through vapor deposition while the substrate 100 is being transported. Thus, the vapor deposition substances (i.e., the vapor deposition materials 101A and 101B) are deposited uniformly onto the bottom surface of the substrate 100.

Here, the vapor deposition temperatures TA and TB of the vapor deposition source 6A and 6B, respectively, are preferably set so that the vapor deposition rate of the vapor deposition material 101A is higher than the vapor deposition rate of the vapor deposition material 101B. Due to this, the pressures PA and PB fulfill PA>PB even after the temperature of the vapor deposition source 6B has reached the vapor deposition temperature TB, which prevents the reverse flow of gases into the housing 20A of the vapor deposition source 6A via the eject outlets 23A of the vapor deposition source 6A. Accordingly, degradation of material characteristics of the vapor deposition material 101A is prevented, which would otherwise occur when undesirable substances discharged from the vapor deposition source 6B enter inside the vapor deposition source 6A and react with the vapor deposition material 101A.

Once the vapor deposition with respect to the substrate 100 is completed, the shutter 7 is closed and the substrate 100 is removed through the exit 5b. Vapor deposition with respect to a plurality of substrates 100 can be performed by repeating the processes up to this point.

When the amount of the vapor deposition materials 101X remaining inside the crucibles 10X becomes small due to the execution of the vapor deposition, the crucibles 10X are supplied with the vapor deposition materials 101X after lowering the temperature of the vapor deposition sources 6X, stopping the vacuum pump, and removing the crucibles 10X from the housings 20X by opening the doors 24X.

The temperatures of the vapor deposition sources 6X are decreased to room temperature after stopping the vacuum pump when the temperatures of the vapor deposition sources 6X have decreased to around the temperatures at which the corresponding vapor deposition materials 101X start to evaporate. Alternatively, the vacuum pump may be stopped after the temperatures of the vapor deposition sources 6X have dropped to room temperature.

<Effects>

As described up to this point, the vapor deposition apparatus 1 performs co-deposition to deposit different vapor deposition materials X onto a vapor deposition target 100, the vapor deposition apparatus 1 including: a chamber 2 accommodating the vapor deposition target 100; a first vapor deposition source 6A ejecting vapor of a first vapor deposition material 101A towards the vapor deposition target 100; a second vapor deposition source 6B ejecting vapor of a second vapor deposition material 101B towards the vapor deposition target 100; a first heater 30A heating the first vapor deposition material 101A; a second heater 30B heating the second vapor deposition material 101B; and a heat controller 40 controlling the first heater 30A and the second heater 30B. The vapor deposition apparatus 1 is characterized in that the heat controller 40 is capable of controlling the first heater 30A and the second heater 30B so that increasing of the temperature of the second vapor deposition material 101B is commenced after a predetermined time period has elapsed from commencement of increasing of the temperature of the first vapor deposition material 101A. Further, a control method of using the vapor deposition apparatus 1 is characterized in that when the first vapor deposition method 101A more readily forms a bond with moisture and/or oxygen compared to the second vapor deposition material 101B, the first heater 30A and the second heater 30B are controlled so that the increasing of the temperature of the second vapor deposition material 101B is commenced after the predetermined time period has elapsed from the commencement of the increasing of the temperature of the first vapor deposition material 101A.

Accordingly, while the vapor deposition source 6A accommodating the vapor deposition material 101A that readily reacts with undesirable substances is being heated, undesirable substances discharged from the vapor deposition source 6B are prevented from entering the vapor deposition source 6A.

Further, the control method is characterized in that the first heater 30A and the second heater 30B are controlled so that a vapor deposition temperature TA of the first vapor deposition material 101A and a vapor deposition temperature TB of the second vapor deposition material 101B are such that a vapor deposition rate of the first vapor deposition material 101A is higher than a vapor deposition rate of the second vapor deposition material 101B. Accordingly, even after the temperature of the vapor deposition source 6A accommodating the vapor deposition material 101A that readily reacts with undesirable substances reaches the vapor deposition temperature TA, undesirable substances discharged from the vapor deposition source 6B are prevented from entering the vapor deposition source 6A. Thus, the reaction between undesirable substances and the vapor deposition material 101A that readily reacts with undesirable substances is prevented through the entire vapor deposition process. Thus, degradation of material characteristics of the vapor deposition materials 101A and 101B is reduced in co-deposition.

<Modification 1>

In the above, description is provided of the vapor deposition apparatus 1 pertaining to embodiment 1, a control method of the vapor deposition apparatus 1, and a vapor deposition method in which the vapor deposition apparatus 1 is used. However, the present invention is not only implementable as exemplified in embodiment 1. That is, the structure exemplified in embodiment 1 can be modified as follows. Specifically, with the vapor deposition apparatus 1 pertaining to embodiment 1 and the vapor deposition method in which the vapor deposition apparatus 1 is used, heating is performed at steep temperature gradients between when the increasing of the temperatures of the vapor deposition materials 101A and 101B is commenced and when the respective vapor deposition temperatures TA and TB are reached. However, any structure suffices as long as the heaters 30A and 30B are controllable such that the increasing of the temperature of the vapor deposition material 101B is commenced after a predetermined time period has elapsed from the commencement of the increasing of the temperature of the vapor deposition material 101A. For example, the following modification may be made.

FIG. 6 schematically illustrates one example of temperature profiles of the vapor deposition sources and a pressure profile inside the chamber 2 in a vapor deposition method in which a vapor deposition apparatus 1 pertaining to modification 1 of embodiment 1 is used. Here, as illustrated in FIG. 6, the heating by the heater 30A is performed such that the temperature of the vapor deposition material 101A is increased in increments from around room temperature to the vapor deposition temperature TA, stopping temporarily at a temperature TA− that is lower than the vapor deposition temperature TA. Similarly, the heating by the heater 30B is performed such that the temperature of the vapor deposition material 101B is increased in increments from around room temperature to the vapor deposition temperature TB, stopping temporarily at a temperature TB− that is lower than the vapor deposition temperature TB.

Specifically, the vapor deposition method in which the vapor deposition apparatus 1 pertaining to modification 1 is used is configured as follows.

First, when the pressure inside the chamber 2 has been dropped to high vacuum pressure P0 at time point t_{A0}, the heater 30A of the vapor deposition source 6A is actuated with the high vacuum pressure P0 maintained inside the chamber 2, to heat the crucible 10A. Between time point t_{A0} and time point t_{A1}, at which the temperature of the vapor deposition source 6A reaches a gas separation temperature TA−, the temperature of the vapor deposition source 6A is increased at a steep temperature gradient. Note that the gas separation temperature TA− is a temperature at which gases of undesirable substances are discharged from the vapor deposition material 101A. More specifically, the gas separation temperature TA− is a temperature at which undesirable substances including moisture having attached to the vapor deposition material 101A separate from the vapor deposition material 101A, and is within a range of for example 100 degrees Celsius to 200 degrees Celsius.

Here, it is expected that by starting to heat the crucible 10A with the pressure inside the chamber 2 reduced to the high vacuum pressure P0, the heating of the crucible 10A can be started with undesirable substances inside the chamber 2 having been removed to a certain extent. Due to this, for example, it is assumed that the reaction between undesirable substances in the chamber 2 and the vapor deposition material 101A can be reduced compared to when the heating of the crucible 10A is started with the pressure inside the chamber 2 remaining at atmospheric pressure.

Subsequently, during a time period between time point t_{A2} and time point t_{A1}, at which the temperature of the vapor deposition source 6A reaches the gas separation temperature TA−, the temperature of the vapor deposition source 6A is kept at a fixed temperature around the gas separation temperature TA− or at a moderate temperature gradient. Specifically, the length of the time period between time point t_{A2} and time point t_{A1} can be determined, for example, by performing analysis of gases to measure the amount of undesirable substances discharged from the vapor deposition material 101A when heated, and determining the amount of time required for sufficient removal of the undesirable substances based on the amount of undesirable substances discharged.

When the temperature of the vapor deposition source 6A exceeds the gas separation temperature TA− of the vapor deposition material 101A, undesirable substances having attached to the vapor deposition material 101A are discharged to the outside of the housing 20A via the eject outlets 23A, and increase the pressure inside the chamber 2. Subsequently, when a sufficient amount of undesirable substances has been removed from the vapor deposition material 101A at time point t_{B0}, the pressure inside the chamber 2 decreases to be around the high vacuum pressure P0 once again. Thus, undesirable substances having entered the housing 20A of the vapor deposition source 6A when supplying the vapor deposition material 101A can be discharged to the outside of the housing 20A.

Further, a configuration is made such that the temperature of the vapor deposition source 6A during the discharge period is equal to or higher than the gas separation temperature TA− and is lower than the vapor deposition temperature TA. This configuration allows evaporating the undesirable substances but not the vapor deposition material 101A during the discharge period. Consequently, this configuration prevents unnecessary consumption of the vapor deposition material, and thus contributes to low cost.

During the time period between time points t_{A2} and t_{A3}, which follows the gas separation time period between time points t_{A1} and t_{A2}, heating is performed until the vapor deposition temperature TA is reached. The vapor deposition temperature TA is a temperature at which the vapor deposition material 101A inside the crucible 10A evaporates, and is within a range of for example 250 degrees Celsius to 350 degrees Celsius.

Subsequently, at time point t_{B0}, the heater 30B of the vapor deposition source 6B is actuated to heat the crucible 10B. Between time point t_{B0} and time point t_{B1}, at which the temperature of the vapor deposition source 6B reaches a gas separation temperature TB−, the vapor deposition source 6B is heated at a steep temperature gradient. Note that the gas separation temperature TB− is a temperature at which gases of undesirable substances are discharged from the vapor deposition material 101B. More specifically, the gas separation temperature TB− is a temperature at which undesirable substances including moisture having attached to the vapor deposition material 101B separate from the vapor deposition material 101B, and is within a range of for example 100 degrees Celsius to 200 degrees Celsius.

Subsequently, during a time period between time point t_{B2} and time point t_{B1}, at which the temperature of the vapor deposition source 6B reaches the gas separation temperature TB−, the temperature of the vapor deposition source 6B is kept at a fixed temperature around the gas separation temperature TB− or at a moderate temperature gradient. Thus, undesirable substances having entered the housing 20B of the vapor deposition source 6B when supplying the vapor deposition material 101B can be discharged to the outside of the housing 20B.

During the time period between time points t_{B2} and t_{B3}, heating is performed until the vapor deposition temperature TB is reached. The vapor deposition temperature TB is a temperature at which the vapor deposition material 101B evaporates, and is within a range of for example 250 degrees Celsius to 350 degrees Celsius. When the temperature of the vapor deposition source 6B exceeds the gas separation temperature of the vapor deposition material 101B, undesirable substances having attached to the vapor deposition material 101B are discharged to the outside of the housing 20B via the eject outlets 23B, and increase the pressure inside the chamber 2. Subsequently, when a sufficient amount of undesirable substances has been removed from vapor deposition material 101B at time point t_{B4}, the pressure inside the chamber 2 is decreased to be around the high vacuum pressure P0 once again.

Once time point t_{B0} is reached, the vapor deposition sources 6A and 6B are maintained at the vapor deposition temperatures TA and TB, respectively. Subsequently, vapor deposition onto the substrate 100 is performed after a sufficient amount of undesirable substances has been removed from the vapor deposition material 101B and the pressure inside the chamber 2 has been decreased to the high vacuum pressure P0 at time point t_{B4}. Specifically, once the evaporation rate of the vapor deposition material 101A and the evaporation rate of the vapor deposition material 101B, which are respectively measured by the sensor 8A and sensor 8B, become stable, the shutter 7 is opened, and the vapor deposition substances are deposited onto the bottom surface of the substrate 100 through vapor deposition while the substrate 100 is being transported. Thus, the vapor deposition substances are deposited uniformly onto the bottom surface of the substrate 100.

In the vapor deposition apparatus 1 pertaining to present modification, as described above, each housing 20X is provided with the eject outlets 23X, which limit the gas circulation between the housing 20X and the chamber 2. Due to this, the vapor deposition materials 101X, when heated, are in a relatively active state, and thus is in a state where the vapor deposition materials 101X readily react with undesirable substances. In particular, when organic materials are used as the vapor deposition materials 101X, degradation of the vapor deposition materials 101X, such as replacement of hydrogen atoms in the molecules of the organic material with OH groups, is likely to occur.

In view of this, the present modification enables discharging undesirable substances having entered the housings 20X of the vapor deposition sources 6X along with the vapor deposition materials 101X to the outside of the housings 20X before vapor deposition is commenced. Thus, the present modification prevents the reaction between the vapor deposition materials 101X and undesirable substances. In addition, maintaining the gas separation temperatures TA− and TB− for a certain period prevents rapid evaporation of undesirable substances.

In addition, similar to embodiment 1, even when the vapor deposition material 101A more readily reacts with moisture and/or oxygen compared to the vapor deposition material 101B, the heaters 30A and 30B are controlled so that the increasing of the temperature of the vapor deposition material 101B is commenced after a predetermined time period has elapsed from the commencement of the increasing of the temperature of the vapor deposition material 101A.

Accordingly, while the vapor deposition source 6A accommodating the vapor deposition material 101A that readily reacts with undesirable substances is being heated, undesirable substances discharged from the vapor deposition source 6B are prevented from entering the vapor deposition source 6A. Consequently, degradation of material characteristics of the vapor deposition materials during the vapor deposition process is reduced.

<Modification 2>

With the vapor deposition apparatus 1 pertaining to embodiment 1 and the vapor deposition method in which the vapor deposition apparatus 1 is used, heating is performed at steep temperature gradients between when increasing of the temperatures of the vapor deposition materials 101A and 101B is commenced and when the respective vapor deposition temperatures TA and TB are reached. However, any structure suffices as long as the heaters 30A and 30B are controllable such that the increasing of the temperature of the vapor deposition material 101B is commenced after a predetermined time period has elapsed from the commencement of the increasing of the temperature of the vapor deposition material 101A. For example, the following modification may be made.

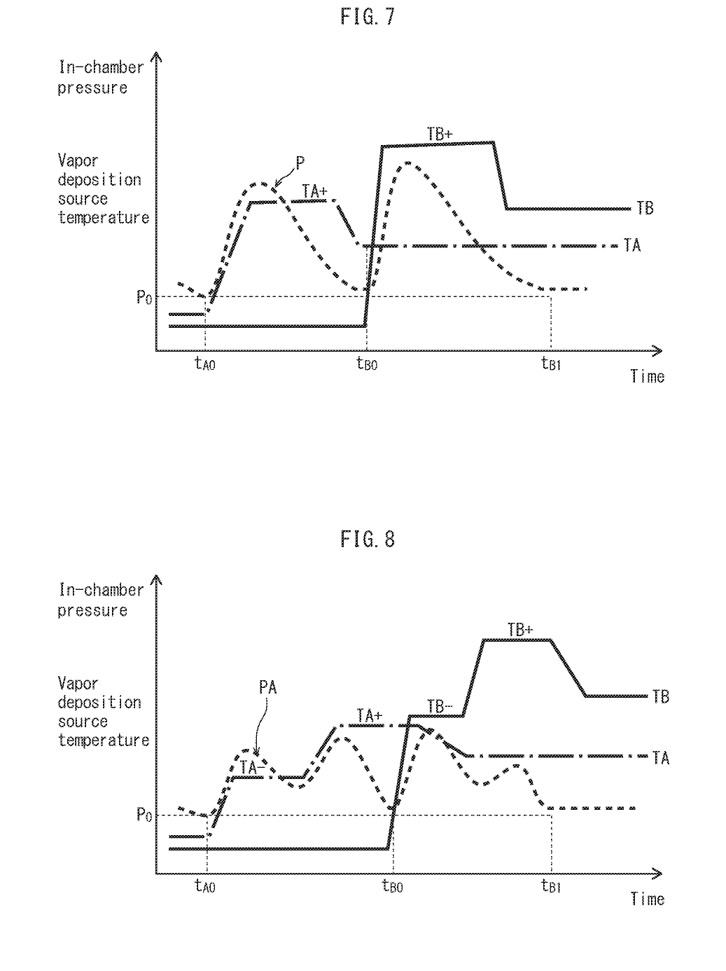

FIG. 7 schematically illustrates one example of temperature profiles of the vapor deposition sources and a pressure profile inside the chamber 2 in a vapor deposition method in which a vapor deposition apparatus 1 pertaining to modification 2 of embodiment 1 is used. As illustrated in FIG. 7, the heating by the heater 30A may be performed such that the temperature of the vapor deposition material 101A is first increased from around room temperature to a temperature TA+ higher than the vapor deposition temperature TA, and then is decreased to the vapor deposition temperature TA. Similarly, the heating by the heater 30B may be performed such that the temperature of the vapor deposition material 101B is first increased from around room temperature to a temperature TB+ higher than the vapor deposition temperature TB, and then is decreased to the vapor deposition temperature TB. This achieves the following effect, in addition to the effects described in embodiment 1. By first increasing the temperature of the vapor deposition material 101X to the temperature TA+ higher than the vapor deposition temperature TA, the amount of time required for removal of undesirable substances from the vapor deposition material 101X can be reduced, the evaporation rates of the vapor deposition materials 101X can be checked with improved stability, and the time period from commencement of the increasing of the temperature of the vapor deposition source 6A to the commencement of vapor deposition can be reduced. Specifically, sufficient removal of undesirable substances from the vapor deposition materials 101X is achieved from time point t_{A0} at which the increasing of the temperature of the vapor deposition source 6A is commenced, and the time period until time point tₘ at which the pressure inside the chamber 2 is decreased to around the high vacuum pressure P0 is reduced.

<Modification 3>

FIG. 8 schematically illustrates one example of temperature profiles of the vapor deposition sources and a pressure profile inside the chamber 2 in a vapor deposition method in which a vapor deposition apparatus 1 pertaining to modification 3 of embodiment 1 is used. As illustrated in FIG. 8, the heating by the heater 30A may be performed such that the temperature of the vapor deposition material 101A is first increased from around room temperature to a temperature TA+ higher than the vapor deposition temperature TA, in increments by stopping temporarily at a temperature TA− that is lower than the vapor deposition temperature TA, and then is decreased to the vapor deposition temperature TA. Similarly, the heating by the heater 30B may be performed such that the temperature of the vapor deposition material 101B is first increased from around room temperature to a temperature TB+ higher than the vapor deposition temperature TB, in increments by stopping temporarily at a temperature TB− that is lower than the vapor deposition temperature TB, and then is decreased to the vapor deposition temperature TB. This modification achieves the effects described in both modifications 1 and 2.

<Modification 4>

With the vapor deposition apparatus 1 pertaining to embodiment 1 and the vapor deposition method in which the vapor deposition apparatus 1 is used, the heaters 30A and 30B are controllable such that the increasing of the temperature of the vapor deposition material 101B is commenced after a predetermined time period has elapsed from the commencement of the increasing of the temperature of the vapor deposition material 101A. Meanwhile, it is also possible to configure the heaters 30A and 30B to be controllable such that the decreasing of the temperature of the vapor deposition material 101A is commenced after a predetermined time period has elapsed from the commencement of the decreasing of the temperature of the vapor deposition material 101B.

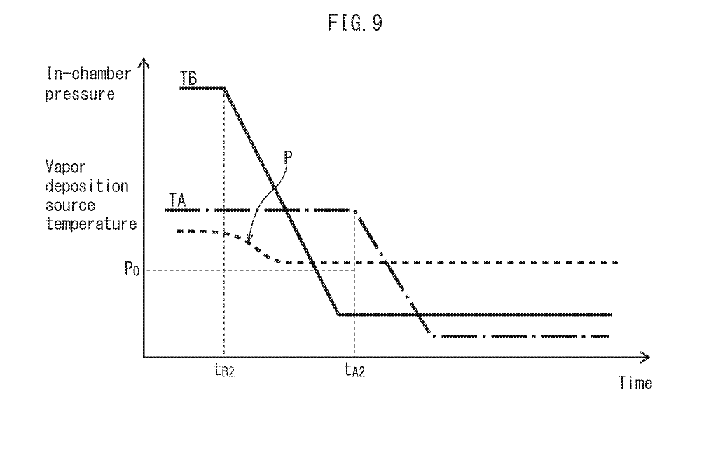

FIG. 9 schematically illustrates one example of temperature profiles of the vapor deposition sources and a pressure profile inside the chamber 2 in a vapor deposition method in which a vapor deposition apparatus 1 pertaining to modification 4 of embodiment 1 is used. As illustrated in FIG. 9, the heaters 30A and 30B may be controlled such that when the vapor deposition material 101A more readily reacts with moisture and/or oxygen compared to the vapor deposition material 101B, the decreasing of the temperature of the vapor deposition material 101A from the vapor deposition temperature TA to around room temperature is commenced later than the decreasing of the temperature of the vapor deposition material 101B from the vapor deposition temperature TB to around room temperature. Further, the decreasing of the temperature of the vapor deposition material 101A may be performed such that the temperature of the vapor deposition material 101A is decreased in increments from the vapor deposition temperature TA to around room temperature, and similarly, the decreasing of the temperature of the vapor deposition material 101B may be performed such that the temperature of the vapor deposition material 101B is decreased in increments from the vapor deposition temperature TB to around room temperature. This achieves the following effect, in addition to the effects described in embodiment 1. Specifically, while the temperature of the vapor deposition source 6A accommodating the vapor deposition material 101A that readily reacts with undesirable substances is being decreased, undesirable substances discharged from the vapor deposition source 6B are prevented from entering the vapor deposition source 6A. Thus, the vapor deposition materials 101B is prevented from mixing with the vapor deposition material 101A before vapor deposition is performed.

### Embodiment 2

(Organic EL Element Manufacturing Process)

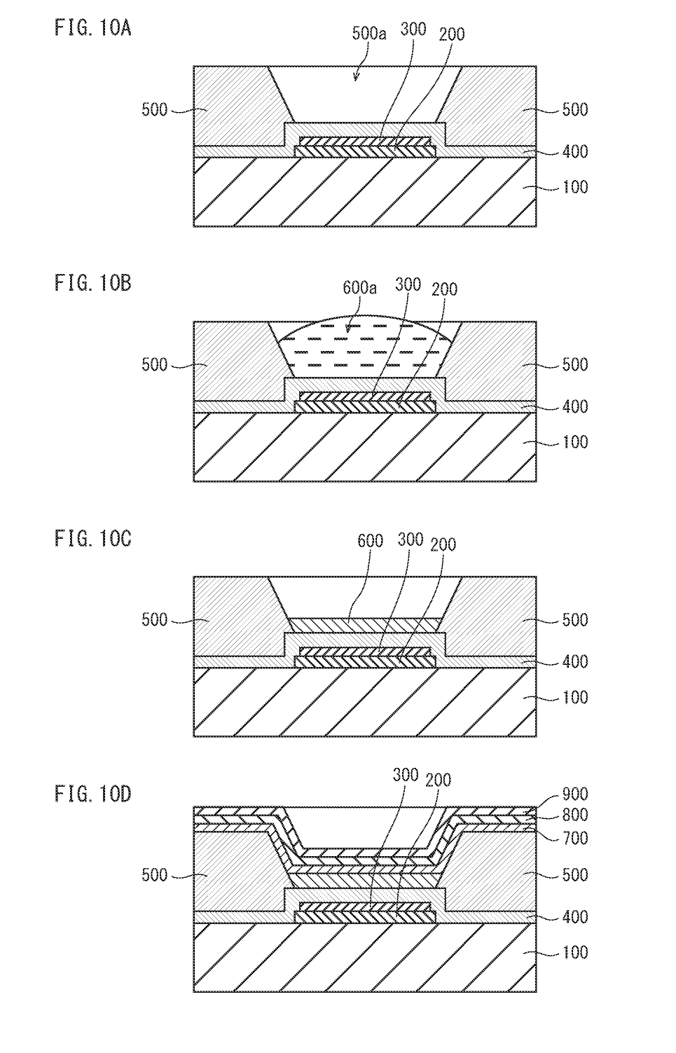

FIGS. 10A through 10D illustrate processes of a device manufacturing method pertaining to embodiment 2, which is a manufacturing method of an organic EL device. FIGS. 10A through 10D illustrate a substrate 100. The substrate 100 is a combination of a TFT substrate and a planarizing film formed on the TFT substrate. The planarizing film is formed by applying a photosensitive resin on the TFT substrate, by exposing the photosensitive resin to light via a photomask, and by performing developing.

As illustrated in FIG. 10A, an anode 200, an ITO layer 300, and a hole injection layer 400 are formed above the substrate 100 in the stated order. Further, banks 500 are formed on the hole injection layer 400. The forming of the banks 500 results in a concave space 500a being formed between the banks 500. The concave space 500a is a space where an element is to be formed.

The anode 200 is formed by forming a thin film of Ag through sputtering for example, and then patterning the thin film of Ag into a matrix through photolithography for example. Note that the thin film of Ag may be formed, for example, through vacuum vapor deposition according to the above-described vapor deposition method.

The ITO layer 300 is formed by forming a thin film of ITO through sputtering for example, and then patterning the thin film of ITO through photolithography for example.

The hole injection layer 400 may be formed by using a composition containing WOₓ or MoₓW_{y}O_{z}, and by performing vacuum vapor deposition according to the above-described vapor deposition method or sputtering, for example.

The banks 500 are formed by forming a layer of bank material by applying the bank material onto the hole injection layer 400, and by removing part of the layer of bank material. The removal of the layer of bank material may be performed by forming a resist pattern on the layer of bank material and then performing etching. Here, note that treatment for providing the surface(s) of the layer of bank material with liquid repellency may be performed when necessary. Such treatment may be plasma treatment in which a fluorine material is used. Here, the banks 500 form a line bank structure, and thus, a plurality of linear banks are formed parallel to one another above the substrate 100.

Subsequently, a light-emitting layer 600 is formed. The light-emitting layer 600 is a functional layer. Specifically, the light-emitting layer 600 is formed as illustrated in FIG. 10B, by filling the concave space 500a between the banks 500, which is the area at which one sub-pixel is to be formed, with ink containing an organic light-emitting layer material through inkjet printing, drying the film formed through the printing, and then performing baking.

FIG. 10C illustrates only one light-emitting layer 600 disposed between one pair of banks 500. However, above the substrate 1, sets of light-emitting layers each composed of a red light-emitting layer, a green light-emitting layer, and a blue light-emitting layer are repeatedly disposed along the lateral direction in FIGS. 10A through 10D. Each light-emitting layer 600 is formed as illustrated in FIG. 10C. Specifically, the concave space 500a is filled with an ink 600a, and the ink 600a is dried under reduced pressure. The ink 600a contains organic light-emitting material corresponding to one of the colors red, green, and blue.

Subsequently, an electron injection layer 700, a cathode 800, and a sealing layer 900 are formed in the stated order as illustrated in FIG. 10D. The electron injection layer 700 may be formed by using an organic material doped with a dopant that is an alkali metal or an alkali earth metal for example, and through co-deposition of the main material (i.e., the organic material) and the additive material (i.e., the dopant) according to a vapor deposition method described above. In this case, the vapor deposition rate of the organic material, which is the main material, is set higher than the vapor deposition rate of the dopant, which is the additive material, and due to this, the internal pressure of the housing accommodating the organic material can be set higher than the internal pressure of the housing accommodating the dopant. Accordingly, the entry of undesirable substances, alkali metal/alkali earth metal compounds, etc., discharged from the housing accommodating the dopant into the housing accommodating the organic material readily reacting with undesirable substances can be prevented.

Further, while not illustrated in any of FIGS. 10A through 10D, a hole transport layer may be formed below the light-emitting layer 600 through a wet process. The hole transport layer is also a functional layer. In addition, an electron transport layer may be formed above the light-emitting layer 600 through a wet process. The electron transport layer is also a functional layer.

The cathode 800 is formed, for example, by forming a thin film of ITO through sputtering.

The sealing layer 900 is formed by applying a resin sealing material and hardening the resin sealing material through UV irradiation. Additionally, a glass plate may be disposed on the sealing layer 900 for further sealing.

Each organic EL device is manufactured through the above-described processes, and as such a device is manufactured.

As described above, forming organic functional layers such as the hole injection layer 400 and the electron transport layer 700 according to the vapor deposition method described in embodiment 1 prevents the reaction between undesirable substances and vapor deposition materials. Thus, degradation of material characteristics of the vapor deposition materials during the vapor deposition process can be reduced. In addition, organic functional layers formed through the vapor deposition contain a small amount of undesirable substances. Further, the vapor deposition methods described in embodiments 1 through 3 are applicable to a metal layer such as a thin film of Ag.

<<Conclusion>>

As described up to this point, the vapor deposition apparatus pertaining to the embodiments is a vapor deposition apparatus that performs co-deposition to deposit different vapor deposition materials onto a vapor deposition target, the vapor deposition apparatus including: a chamber accommodating the vapor deposition target; a first vapor deposition source ejecting vapor of a first vapor deposition material towards the vapor deposition target; a second vapor deposition source ejecting vapor of a second vapor deposition material differing from the first vapor deposition material towards the vapor deposition target; a first heater heating the first vapor deposition material; a second heater heating the second vapor deposition material; and a heat controller controlling the first and second heaters. The vapor deposition apparatus is configured so that the heat controller is capable of controlling the first and second heaters so that increasing of the temperature of the second vapor deposition material is commenced after a predetermined time period has elapsed from commencement of increasing of the temperature of the first vapor deposition material.

Accordingly, undesirable substances ejected from one vapor deposition source are prevented from entering another vapor deposition source that accommodates a vapor deposition material that readily reacts with undesirable substances. Thus, the reaction between undesirable substances and the vapor deposition material that readily reacts with undesirable substances such as moisture is prevented. Thus, degradation of material characteristics of vapor deposition material occurring in co-deposition is reduced.

<<Other Modifications>>

1. In the embodiments, only two vapor deposition sources 6 are disposed inside the chamber 2. However, three or more vapor deposition sources may be disposed inside the chamber, and when making such a modification, undesirable adhesion of the crucible to the housing may be prevented by applying the structure described in the embodiments to each vapor deposition source.

2. In the embodiments, the housings 20 of the vapor deposition sources 6 are disposed on a bottom plate of the chamber 2, as illustrated in FIG. 1. However, the housings 20 and the chamber 2 may be formed integrally.

3. In the embodiments, description is provided of a case where each vapor deposition source is a so-called line source and has an elongated shape. However, the vapor deposition sources need not be line sources, and similar implementation is possible with, for example, cylindrical vapor deposition sources. That is, as long as each vapor deposition source has a housing defining a concave space in which a crucible can be accommodated and a lid covering an opening of the concave space and having a plurality of eject outlets disposed therein, the effect of preventing undesirable adhesion of the crucible to the housing may be similarly achieved by, for example, providing a plurality of support protrusions to the bottom surface, the brim, or the like of the crucible, and/or to the housing, regardless of the shape of the vapor deposition sources.

4. In embodiment 2, the light-emitting layer 600 is formed through applying ink with respect to the substrate by using an ink droplet ejection device having a single inkjet head. However, the light-emitting layer 600 may be formed, for example, through vapor deposition. When forming the light-emitting layer 600 through vapor deposition, the vapor deposition methods described in embodiments 1 and 2 may be applied. By applying this method, the inclusion of undesirable substances in organic functional layers, including the light-emitting layer 600, can be prevented.

5. The above-described order in which processes are carried out is a mere example used for providing specific description of the present invention. Accordingly, the processes may be carried out in an order differing from that described above. Further, some of the processes may be carried out simultaneously (in parallel). In addition, at least some of the device manufacturing methods and functions of modifications thereof, which are described in the embodiments, may be combined with one another. Further, the present invention shall be construed as including various modifications that skilled artisans may arrive at based on the embodiments.

<<Supplement>>

The embodiments described above are mere preferable examples of how the present invention may be specifically implemented. As such, values, shapes, materials, components, arrangement positions of components, connections between components, processes, and the order in which processes are carried out described above are mere examples, and shall not be construed as limiting the present invention. Further, among the components described in the embodiments, those that are not recited in the independent claims, which describe the present invention using the broadest of concepts, shall be construed as being components that may be and may not be included in preferable forms of implementation of the present invention.

In addition, the drawings referred to in the embodiments may illustrate components at sizes differing from their actual sizes, in order to facilitate understanding of the invention. Further, the present invention shall not be construed as being limited to what is disclosed in the embodiments, and instead, shall be construed as including various modifications that do not depart from the spirit and scope thereof.

Further, a vapor deposition apparatus typically includes members such as circuit components and lead wires disposed on and above a substrate. However, the description provided up to this point does not include description of such electrical wiring and electrical circuits for not being directly necessary in describing the present invention, and electrical wiring and electrical circuits may be implemented in various forms based on common knowledge in the technical field. In addition, the drawings referred to in the above are schematics, and as such, do not necessarily provide precise illustration.

### INDUSTRIAL APPLICABILITY

The present invention is widely applicable in general to the manufacturing of devices that may be manufactured by using a vapor deposition apparatus and through vapor deposition, such as organic light-emitting elements and TFT substrates.

### REFERENCE SIGNS LIST

1 vapor deposition apparatus

2 chamber

3 chamber air outlet

4 partition plate

4a window

5a entrance

5b exit

6 (6A, 6B, (6X)) vapor deposition sources (first and second vapor deposition sources)

7 shutter

8 (8A, 8B) sensors

10 (10A, 10B, (10X)) crucibles

20 (20A, 20B, (20X)) housings

21 (21A, 21B, (21X)) housing main bodies

21a (21aA, 21aB, (21aX)) bottom plates

21b (21bA, 21bB, (21bX)) circumferential walls

22 (22A, 22B, (22X)) lids

30 (30A, 30B, (30X)) heaters (first and second heaters)

40 heat controller

100 substrate (vapor deposition target)

101 (101A, 101B, (101X)) vapor deposition materials (first and second vapor deposition materials)

1. A vapor deposition method for depositing different vapor deposition materials onto a vapor deposition target, the vapor deposition method comprising:
providing the vapor deposition target in a chamber;
heating, via a first heater, a first vapor deposition material for a predetermined period for increasing a temperature of the first vapor deposition material;
ejecting, from a first vapor deposition source, vapor of the first vapor deposition material towards the vapor deposition target;
heating, after the predetermined period has elapsed and via a second heater different from the first heater, the second vapor deposition material for increasing a temperature of a second vapor deposition material; and
ejecting, from a second vapor deposition source, vapor of the second vapor deposition material differing from the first vapor deposition material towards the vapor deposition target,
wherein
the first vapor deposition material is a main material containing an organic functional material, and the second vapor deposition material is an additive material containing a metal material.

2. The vapor deposition method of claim 1, wherein
controlling the first heater and the second heater, such that a vapor deposition temperature of the first vapor deposition material and a vapor deposition temperature of the second vapor deposition material are such that a vapor deposition rate of the first vapor deposition material is higher than a vapor deposition rate of the second vapor deposition material.

3. The vapor deposition method of claim 1, further comprising:
increasing, via the first heater, the temperature of the first vapor deposition material from a room temperature to a vapor deposition temperature of the first vapor deposition material in increments; and
increasing, via the second heater, the temperature of the second vapor deposition material from the room temperature to a vapor deposition temperature of the second vapor deposition material in increments.

4. The vapor deposition method of claim 1, further comprising:
increasing, via the first heater, the temperature of the first vapor deposition material from a room temperature to a temperature higher than a vapor deposition temperature of the first vapor deposition material; and
after reaching the temperature higher than the vapor deposition temperature of the first vapor deposition material, decreasing the temperature of the first vapor deposition material to the vapor deposition temperature of the first vapor deposition material.

5. The vapor deposition method of claim 4, further comprising:
increasing, via the second heater, the temperature of the second vapor deposition material from the room temperature to a temperature higher than the vapor deposition temperature of the second vapor deposition material, and
after reaching the temperature higher than the vapor deposition temperature of the second vapor deposition material, decreasing the temperature of the second vapor deposition material to the vapor deposition temperature of the second vapor deposition material.

6. The vapor deposition method of claim 1, further comprising:
decreasing, by the second heater, the temperature of the second vapor deposition material from a vapor deposition temperature of the second vapor deposition material to a room temperature; and
after the decrease of the temperature of the second vapor deposition material to the room temperature, decreasing, by the first heater, the temperature of the first vapor deposition material from a vapor deposition temperature of the first vapor deposition material to the room temperature.

7. The vapor deposition method of claim 6, further comprising:
decreasing, via the first heater, the temperature of the first vapor deposition material from the vapor deposition temperature of the first vapor deposition material to the room temperature in increments; and
decreasing, via the second heater, the temperature of the second vapor deposition material from the vapor deposition temperature of the second vapor deposition material to the room temperature in increments.

8. A vapor deposition method for depositing different vapor deposition materials onto a vapor deposition target, the vapor deposition method comprising:
providing the vapor deposition target in a chamber;
heating, via a first heater, a first vapor deposition material for a predetermined period for increasing a temperature of the first vapor deposition material;
ejecting, from a first vapor deposition source, vapor of the first vapor deposition material to spread inside of the chamber and towards the vapor deposition target;
heating, after the predetermined period has elapsed and via a second heater different from the first heater, a second vapor deposition material for increasing a temperature of the second vapor deposition material;
ejecting, from a second vapor deposition source, vapor of the second vapor deposition material differing from the first vapor deposition material to spread inside of the chamber and towards the vapor deposition target;
controlling, at least one of the first heater and the second heater, such that a pressure inside the second vapor deposition source is greater than a pressure inside the first vapor deposition source, to cause a reverse flow of gasses from the chamber into the first vapor deposition source,
wherein
the first vapor deposition material is a main material containing an organic functional material, and the second vapor deposition material is an additive material containing a metal material.
